(19) United States
(12) Patent Application Publication
(10) Pub. No.: US 2009/0231060 A1
(43) Pub. Date: Sep. 17, 2009

(54) Ladder resonator filter and related system

(75) Inventor: Anatoly Rusakov, Dallas, TX (US)

Correspondence Address: DOCKET CLERK, P.O. DRAWER 800889, DALLAS, TX, 75380, US

(73) Assignee: RF Monolithics, Inc., Dallas, TX (US)

(21) Appl. No.: 12/075,422

(22) Filed: Mar. 11, 2008

(51) Int. Cl. H03H 9/64

(52) U.S. Cl. 333/195

(57) ABSTRACT

An apparatus includes a plurality of resonators forming a filter. At least one of the resonators includes (i) a plurality of interdigital transducers positioned in a common acoustic track and (ii) a plurality of reflectors configured to reflect acoustic waves from the interdigital transducers back to the interdigital transducers. At least one reflector is positioned between adjacent interdigital transducers. The interdigital transducers in one of the resonators could be coupled in parallel or in series between an input and an output of that resonator.

### TECHNICAL FIELD

This disclosure is generally directed to filters and more specifically to a ladder resonator filter and related system.

### BACKGROUND

Surface acoustic wave (SAW) ladder resonator filters are routinely used to filter signals. The SAW ladder resonator filters often include multiple SAW resonators that are arranged to provide desired filtering functionality. A typical SAW ladder resonator filter includes five to ten resonators that are coupled together. One problem with conventional SAW ladder resonator filters is that each of the resonators is placed in its own acoustic track on a substrate. This is done to help reduce or prevent interactions between the resonators. However, this increases the size of the SAW ladder resonator filters and the associated costs of the SAW ladder resonator filters. Also, this type of layout increases the length and complexity of interconnections between the resonators in the SAW ladder resonator filters.

### SUMMARY

This disclosure provides a ladder resonator filter and related system.

In a first embodiment, an apparatus includes a plurality of resonators forming a filter. At least one of the resonators includes (i) a plurality of interdigital transducers positioned in a common acoustic track and (ii) a plurality of reflectors configured to reflect acoustic waves from the interdigital transducers back to the interdigital transducers. At least one reflector is positioned between adjacent interdigital transducers.

In particular embodiments, the interdigital transducers in one of the resonators are coupled in parallel or in series between an input and an output of that resonator.

In other particular embodiments, the interdigital transducers in a first of the resonators are coupled in parallel between an input of the first resonator and ground. The interdigital transducers in a second of the resonators are coupled in series between the input of the first resonator and an output of the second resonator. The interdigital transducers in a third of the resonators are coupled in parallel between the output of the second resonator and ground. Each of the first, second, and third resonators could include two interdigital transducers and three reflectors.

In yet other particular embodiments, each of the interdigital transducers includes multiple sets of electrodes. At least some of the reflectors are electrically coupled to at least some of the sets of electrodes in the interdigital transducers. At least some of the reflectors are electrically coupled together.

In still other particular embodiments, the interdigital transducers in a first of the resonators are coupled in series between an input of the first resonator and an output of the first resonator. The interdigital transducers in a second of the resonators are coupled in parallel between the output of the first resonator and ground. The interdigital transducers in a third of the resonators are coupled in series between the output of the first resonator and an output of the third resonator. Each of the first, second, and third resonators could include two interdigital transducers and three reflectors.

In additional particular embodiments, the plurality of resonators forming the filter include resonators forming at least two Π sections or at least two T sections in the filter.

In a second embodiment, a system includes a signal source configured to provide a signal and a filter configured to filter the signal. The filter includes a plurality of resonators. At least one of the resonators includes (i) a plurality of interdigital transducers positioned in a common acoustic track and (ii) a plurality of reflectors configured to reflect acoustic waves from the interdigital transducers back to the interdigital transducers. At least one reflector is positioned between adjacent interdigital transducers.

In particular embodiments, the system further includes a signal processor configured to process a filtered signal provided by the filter.

In other particular embodiments, the signal source includes an antenna.

In a third embodiment, a resonator includes a plurality of interdigital transducers positioned in a common acoustic track. The resonator also includes a plurality of reflectors configured to reflect acoustic waves from the interdigital transducers back to the interdigital transducers. At least one reflector is positioned between adjacent interdigital transducers.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIGS. 1A and 1B illustrate example ladder resonator filters according to this disclosure;

FIGS. 2 and 3 illustrate example resonators within the ladder resonator filters of FIGS. 1A and 1B according to this disclosure;

FIGS. 4 and 5 illustrate example operation of an interdigital transducer within the ladder resonator filters of FIGS. 1A and 1B according to this disclosure;

FIGS. 6 and 7 illustrate additional details of the ladder resonator filter of FIG. 1A according to this disclosure;

FIG. 8 illustrates additional details of the ladder resonator filter of FIG. 1B according to this disclosure; and

FIG. 9 illustrates an example system using a ladder resonator filter according to this disclosure.

### DETAILED DESCRIPTION

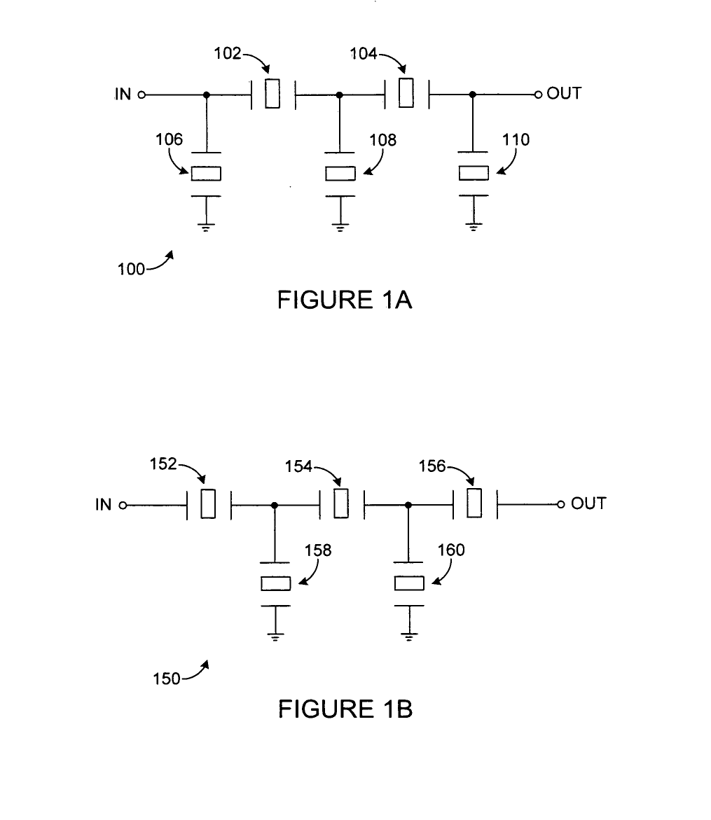

FIGS. 1 through 9, discussed below, and the various embodiments used to scribe the principles of the present invention in this patent document are by way of illustration only and should not be construed in any way to limit the scope of the invention. Those skilled in the art will understand that the principles of the invention may be implemented in any type of suitably arranged device or system.

FIGS. 1A and 1B illustrate example ladder resonator filters according to this disclosure. The embodiments of the ladder resonator filters shown in FIGS. 1A and 1B are for illustration only. Other embodiments of the ladder resonator filters could be used without departing from the scope of this disclosure.

As shown in FIG. 1A, a ladder resonator filter 100 receives an input signal IN and produces a filtered output signal OUT. The ladder resonator filter 100 in this example includes five resonators 102-110. The resonators 102-104 are coupled in series with each other, and the resonators 106-110 are coupled in parallel with each other. In this example, the ladder resonator filter 100 is said to include two “Π” sections, where “Π” denotes the shape of the two sections. One “Π” section includes the resonators 106, 102, and 108. The other “Π” section includes the resonators 108, 104, and 110.

As shown in FIG. 1B, a ladder resonator filter 150 is similar in structure to the ladder resonator filter 100. The ladder resonator filter 150 in this example includes five resonators 152-160. The resonators 152-156 are coupled in series with each other, and the resonators 158-160 are coupled in parallel with each other. In this example, the ladder resonator filter 150 is said to include two “T” sections. One “T” section includes the resonators 152, 154, and 158. The other “T” section includes the resonators 154, 156, and 160.

While each of the resonators 102-110 appears as a single unit in FIG. 1A, each of these resonators 102-110 could represent a collection of resonators. Also, as described in more detail below, the resonators 102-110 in the ladder resonator filter 100 could be formed in the same acoustic track of a substrate. Similarly, while each of the resonators 152-160 appears as a single unit in FIG. 1B, each of these resonators 152-160 could represent a collection of resonators. Moreover, as described in more detail below, the resonators 152-160 in the ladder resonator filter 150 could be formed in the same acoustic track of a substrate. Among other things, this may allow the ladder resonator filters 100 and 150 to occupy less physical space, resulting in reduced area and lower associated manufacturing costs. This may also help to simplify the connections between resonators in the ladder resonator filters 100 and 150.

Although FIGS. 1A and 1B illustrate examples of ladder resonator filters 100 and 150, various changes may be made to FIGS. 1A and 1B. For example, each of the ladder resonator filters 100 and 150 could include any suitable number of sections, and filters having non-uniform or no sections could be used. Also, each of the sections in the ladder resonator filters 100 and 150 could include any suitable number and arrangement of resonators.

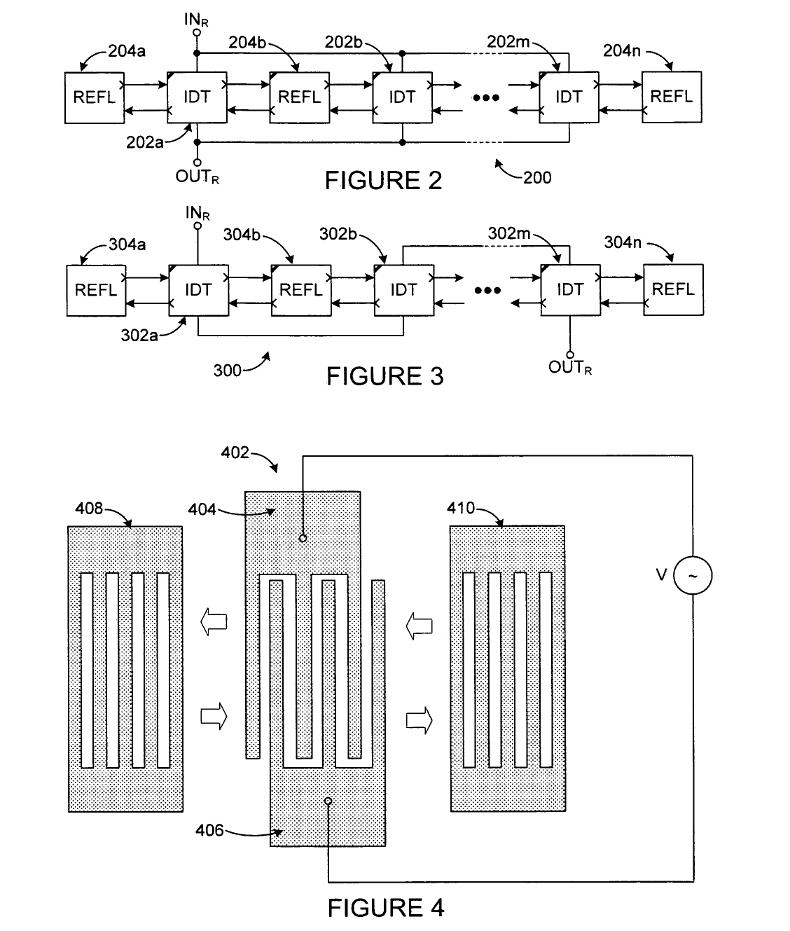

FIGS. 2 and 3 illustrate example resonators within the ladder resonator filters of FIGS. 1A and 1B according to this disclosure. The embodiments of the resonators shown in FIGS. 2 and 3 are for illustration only. Other embodiments of the resonators could be used without departing from the scope of this disclosure.

As shown in FIG. 2, a resonator 200 includes multiple interdigital transducers (IDTs) 202a-202m and multiple reflectors 204a-204n. Each of the interdigital transducers 202a-202m typically includes multiple sets of conductive electrodes that are interleaved. Each of the interdigital transducers 202a-202m includes any suitable structure having multiple sets of interleaved conductive electrodes.

The interdigital transducers 202a-202m are located between pairs of the reflectors 204a-204n. For example, the interdigital transducer 202a is located between the reflectors 204a-204b. In other words, adjacent interdigital transducers are separated by at least one of the reflectors. Each of the reflectors 204a-204n includes any suitable structure for reflecting acoustic waves, such as a non-interleaved set of electrodes.

In this example, the interdigital transducers 202a-202m are generally coupled in parallel with one another between a resonator input IN_{R} and a resonator output OUT_{R}. In other words, the interdigital transducers 202a-202m all have “inputs” that are coupled to the resonator input IN_{R} and “outputs” that are coupled to the resonator output OUT_{R}. During operation of the resonator 200, each of the interdigital transducers 202a-202m generally produces acoustic waves that propagate in the resonator 200. The reflectors 204a-204n generally operate to reflect waves from an interdigital transducer back to that interdigital transducer. In this way, multiple interdigital transducers 202a-202m can be located in the same acoustic track without unduly interfering with each other.

As shown in FIG. 3, a resonator 300 includes multiple interdigital transducers 302a-302m and multiple reflectors 304a-304n. Each of the interdigital transducers 302a-302m is located between a pair of the reflectors 304a-304n. Each of the interdigital transducers 302a-302m includes any suitable structure having multiple sets of interleaved conductive electrodes. Each of the reflectors 304a-304n includes any suitable structure for reflecting acoustic waves, such as a non-interleaved set of electrodes.

In this example, the interdigital transducers 302a-302m are generally coupled in series with one another between a resonator input IN_{R} and a resonator output OUT_{R}. In other words, the interdigital transducer 302a has an “input” that is coupled to the resonator input IN_{R}, and each remaining interdigital transducer 302b-302m has an “input” that is coupled to an “output” of the prior interdigital transducer. During operation of the resonator 300, each of the interdigital transducers 302a-302m generally produces acoustic waves that propagate in the resonator 300, and the reflectors 304a-304n generally operate to reflect waves from an interdigital transducer back to that interdigital transducer. In this way, multiple interdigital transducers 302a-302m can be located in the same acoustic track without unduly interfering with each other.

In some embodiments, the resonator 200 of FIG. 2 could be used as the resonators 106-110 in the ladder resonator filter 100 of FIG. 1A and as the resonators 158-160 in the ladder resonator filter 150 of FIG. 1B. Also, the resonator 300 of FIG. 3 could be used as the resonators 102-104 in the ladder resonator filter 100 of FIG. 1A and as the resonators 152-156 in the ladder resonator filter 150 of FIG. 1B.

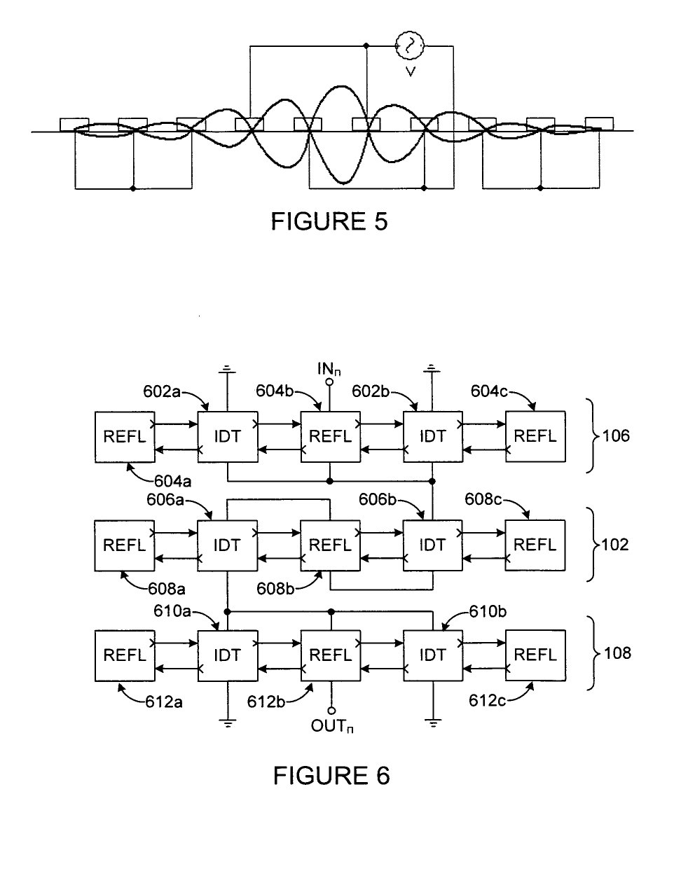

An example operation of the interdigital transducers and reflectors in the ladder resonator filters 100 and 150 is illustrated in FIGS. 4 and 5. In FIG. 4, an interdigital transducer 402 is formed from two sets 404-406 of interleaved conductive electrodes. Two reflectors 408-410 are positioned on opposite sides of the resonator 402. The reflectors 408-410 include conductive electrodes that are generally parallel to the sets 404-406 of interleaved conductive electrodes in the interdigital transducer 402. By applying a voltage across the interdigital transducer 402, the interdigital transducer 402 generates acoustic waves that propagate substantially normal to the sets 404-406 of electrodes. The reflectors 408-410 reflect those waves back to the interdigital transducer 402. As shown in FIG. 5, when the waves being reflected and the waves being generated by the interdigital transducer 402 are in phase, a standing wave is created at a resonance frequency. Away from its resonance frequency, the interdigital transducer 402 acts like a static capacitor, while a large current is provided at the resonance frequency.

In general, the reflectors 204a-204n and 304a-304n have a reflection band where the reflection coefficient is almost one. A stop band of the interdigital transducers 202a-202m and 302a-302m is the frequency range where the transmission coefficient is almost zero and waves can propagate. In the resonators 200 and 300, the reflection coefficient of the reflectors is small outside of the reflection band, while the reflection coefficient of the reflectors is strong within the stop band of the interdigital transducers. Outside of the reflection band, this allows the resonator 200 or 300 to work as a resonator with long ID_{T}. Inside of the reflection band, this allows the resonator 200 or 300 to work as several separated short resonators. This could represent optimal operations both inside and outside of the reflection band.

In particular embodiments, the ladder resonator filters 100 and 150 are formed on a lithium tantalite (LiTaO₃) substrate. Each interdigital transducer in the resonators 102-110 and 152-160 (implemented as shown in FIGS. 2 and 3) may include between 150-250 electrodes, and each reflector in the resonators 102-110 and 152-160 may include between 30-70 electrodes. Further, the interdigital transducers and the reflectors may have identical periods for the electrodes, and there may be no shift between the electrodes in the interdigital transducers and the reflectors. In addition, the aperture (the space between electrodes in the interdigital transducers and the reflectors) could have a size of between 10λ-15λ, where λ represents the center wavelength of the signal being filtered.

Although FIGS. 2 and 3 illustrate examples of resonators within the ladder resonator filters of FIGS. 1A and 1B, various changes may be made to FIGS. 2 and 3. For example, the resonator 200 could include any suitable number of interdigital transducers coupled in parallel and separated by reflectors, including two or more interdigital transducers. Similarly, the resonator 300 could include any suitable number of interdigital transducers coupled in series and separated by reflectors, including two or more interdigital transducers.

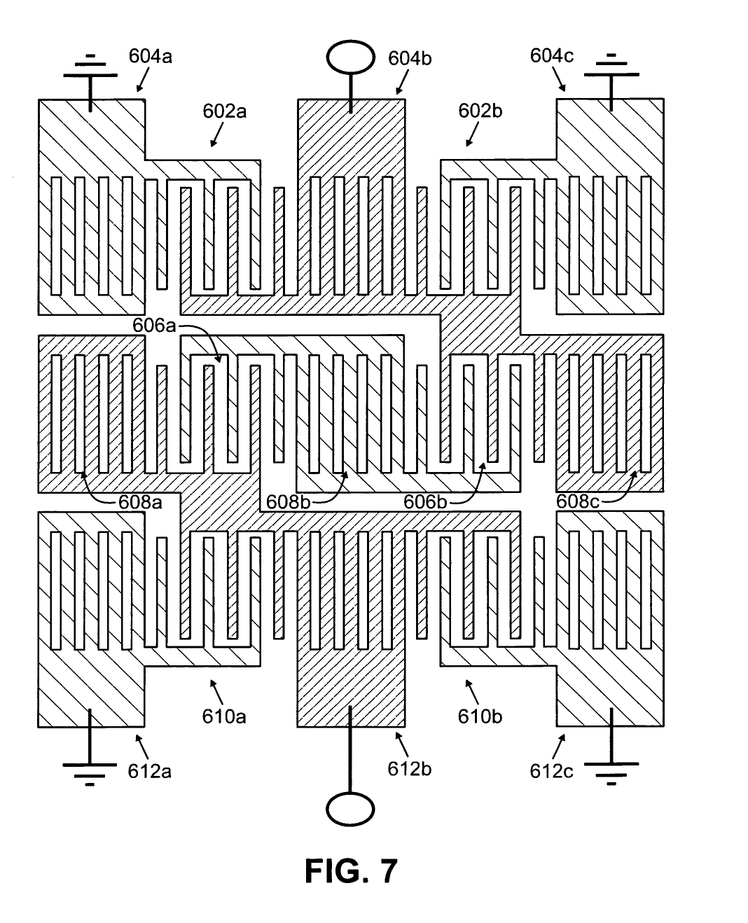

FIGS. 6 and 7 illustrate additional details of the ladder resonator filter 100 of FIG. 1A according to this disclosure. In particular, FIGS. 6 and 7 illustrate one example implementation of a single “Π” section of the ladder resonator filter 100 of FIG. 1A. The additional details shown in FIGS. 6 and 7 are for illustration only. The ladder resonator filter 100 of FIG. 1A could be implemented in any other suitable manner without departing from the scope of this disclosure.

As shown in FIG. 6, the resonator 106 in FIG. 1A is implemented using the same technique shown in FIG. 2. Here, two interdigital transducers 602a-602b are isolated by three reflectors 604a-604c. The interdigital transducers 602a-602b are coupled in parallel between an input IN_{Π} of the section and ground. The reflectors 604a-604c operate to generally reflect waves from each interdigital transducer 602a-602b back to that interdigital transducer, which helps to isolate the interdigital transducers 602a-602b.

The resonator 102 in FIG. 1A is implemented using the same technique shown in FIG. 3. Here, two interdigital transducers 606a-606b are isolated by three reflectors 608a-608c. The interdigital transducers 606a-606b are coupled in series between an output of the resonator 106 and an input of the resonator 108. The reflectors 608a-608c operate to generally reflect waves from each interdigital transducer 606a-606b back to that interdigital transducer, which helps to isolate the interdigital transducers 606a-606b.

The resonator 108 in FIG. 1A is implemented using the same technique shown in FIG. 2. Here, two interdigital transducers 610a-610b are isolated by three reflectors 612a-612c. The interdigital transducers 610a-610b are coupled in parallel between an output of the resonator 102 and an output OUT_{N} of the section. The reflectors 612a-612c operate to generally reflect waves from each interdigital transducer 610a-610b back to that interdigital transducer, which helps to isolate the interdigital transducers 610a-610b.

One example layout of the “Π” section of the ladder resonator filter 100 from FIG. 6 is shown in FIG. 7. It may be noted that various ones of the reflectors 604a-604c, 608a-608c, 612a-612c are electrically connected to portions of the interdigital transducers 602a-602b, 606a-606b, 610a-610b. For example, the reflector 604a is electrically connected to one of the sets of electrodes in the interdigital transducer 602a, and the reflector 604c is electrically connected to one of the sets of electrodes in the interdigital transducer 602b. The reflector 604b is electrically connected to both (i) another of the sets of electrodes in the interdigital transducer 602a and (ii) another of the sets of electrodes in the interdigital transducer 602b. Moreover, various ones of the reflectors 604a-604c, 608a-608c, 612a-612c are electrically connected to each other. For example, the reflector 604b is electrically connected to the reflector 608c, and the reflector 608a is electrically connected to the reflector 612b.

As noted above, FIGS. 6 and 7 illustrate one example implementation of a single “Π” section of the ladder resonator filter 100 of FIG. 1A. The same or similar implementation could be used to form one or more additional “Π” sections of the ladder resonator filter 100 of FIG. 1A (to thereby form a complete filter).

Implementing one, some, or all of the “Π” sections of the ladder resonator filter 100 in this way allows the resonators within the ladder resonator filter 100 to be located in a single acoustic track. This may help the ladder resonator filter 100 to have a smaller size. This may also help to provide simpler and shorter interconnections between resonators.

Although FIGS. 6 and 7 illustrate additional details of one example implementation of the ladder resonator filter 100 of FIG. 1A, various changes may be made to FIGS. 6 and 7. For example, each of the resonators 102, 106, and 108 in FIG. 6 could include any suitable number of interdigital transducers (such as more than two).

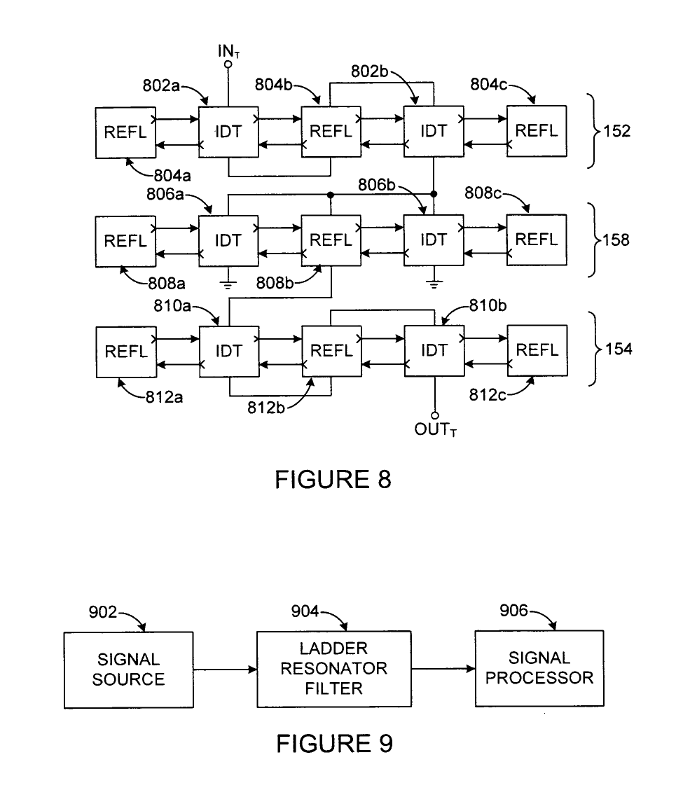

FIG. 8 illustrates additional details of the ladder resonator filter 150 of FIG. 1B according to this disclosure. In particular, FIG. 8 illustrates one example implementation of a single “T” section of the ladder resonator filter 150 of FIG. 1B. The additional details shown in FIG. 8 are for illustration only. The ladder resonator filter 150 of FIG. 1B could be implemented in any other suitable manner without departing from the scope of this disclosure.

As shown in FIG. 8, the resonator 152 in FIG. 1B is implemented using the same technique shown in FIG. 3. Here, two interdigital transducers 802a-802b are isolated by three reflectors 804a-804c. The interdigital transducers 802a-802b are coupled in series between an input IN_{T} of the section and an input of the resonator 158. The reflectors 804a-804c operate to generally reflect waves from each interdigital transducer 802a-802b back to that interdigital transducer, which helps to isolate the interdigital transducers 802a-802b.

The resonator 158 in FIG. 1B is implemented using the same technique shown in FIG. 2. Here, two interdigital transducers 806a-806b are isolated by three reflectors 808a-808c. The interdigital transducers 806a-806b are coupled in parallel between an output of the resonator 152 and ground. The reflectors 808a-808c operate to generally reflect waves from each interdigital transducer 806a-806b back to that interdigital transducer, which helps to isolate the interdigital transducers 806a-806b.

The resonator 154 in FIG. 1B is implemented using the same technique shown in FIG. 3. Here, two interdigital transducers 810a-810b are isolated by three reflectors 812a-812c. The interdigital transducers 810a-810b are coupled in series between an output of the resonator 158 and an output OUT_{T} of the section. The reflectors 812a-812c operate to generally reflect waves from each interdigital transducer 810a-810b back to that interdigital transducer, which helps to isolate the interdigital transducers 810a-810b.

An example layout of the “T” section could be similar to that shown in FIG. 7, with modifications to support the different structure of the resonators 152, 154, 158 and to support the appropriate connections between the resonators 152, 154, 158. Also, as noted above, FIG. 8 illustrate one example implementation of a single “T” section of the ladder resonator filter 150 of FIG. 1B. The same or similar implementation could be used to form one or more additional “T” sections of the ladder resonator filter 150 of FIG. 1B (to thereby form a complete filter 150).

Implementing one, some, or all of the “T” sections of the ladder resonator filter 150 in this way allows the resonators within the ladder resonator filter 150 to be located in a single acoustic track. This may help the ladder resonator filter 150 to have a smaller size and to provide simpler and shorter interconnections between resonators.

Although FIG. 8 illustrates additional details of one example implementation of the ladder resonator filter 150 of FIG. 1B, various changes may be made to FIG. 8. For example, each of the resonators 152, 154, and 158 in FIG. 8 could include any suitable number of interdigital transducers (such as more than two).

FIG. 9 illustrates an example system 900 using a ladder resonator filter according to this disclosure. The embodiment of the system 900 shown in FIG. 9 is for illustration only. Other embodiments of the system 900 could be used without departing from the scope of this disclosure.

In FIG. 9, a signal source 902 provides a signal to a ladder resonator filter 904, which filters the signal for processing by a signal processor 906. The signal source 902 represents any suitable source of a signal that is filtered by the ladder resonator filter 904. The signal source 902 could, for example, represent a component that generates the signal being filtered by the ladder resonator filter 904. In this case, the signal source 902 could represent any suitable structure that generates a signal. The signal source 902 could also represent a component that receives from an external source the signal being filtered by the ladder resonator filter 904. In this case, the signal source 902 could represent any other suitable structure that receives a signal, such as an antenna.

The ladder resonator filter 904 represents a filter for filtering the signal from the signal source 902. The ladder resonator filter 904 could represent any suitable filter that includes multiple resonators coupled in series and/or in parallel, where the resonators are separated by reflectors and can be placed in a single acoustic track of a substrate. This includes the ladder resonator filters 100 and 150 described above.

The signal processor 906 processes the filtered signal from the ladder resonator filter 904. The signal processor 906 represents any suitable component that can further process the signal filtered by the ladder resonator filter 904. The signal processor 906 could, for example, represent a digital processing component, such as a microprocessor, microcontroller, or digital signal processor (DSP). In this case, an analog-to-digital converter could be used to digitize the filtered signal from the filter 904. The signal processor 906 could also represent analog processing components, such as mixers or amplifiers. The signal processor 906 may generally include any component(s) for processing the signal from the ladder resonator filter 904. The actual makeup and arrangement of the signal processor 906 depends, among other things, on the specific application for the system 900.

Although FIG. 9 illustrates one example of a system 900 using a ladder resonator filter, various changes may be made to FIG. 9. For example, the ladder resonator filters 100 and 150 described above could be used in any other suitable system.

It may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising a plurality of resonators forming a filter, at least one of the resonators comprising:
a plurality of interdigital transducers positioned in a common acoustic track; and
a plurality of reflectors configured to reflect acoustic waves from the interdigital transducers back to the interdigital transducers, wherein at least one reflector is positioned between adjacent interdigital transducers.

2. The apparatus of claim 1, wherein the interdigital transducers in one of the resonators are coupled in parallel between an input and an output of that resonator.

3. The apparatus of claim 1, wherein the interdigital transducers in one of the resonators are coupled in series between an input and an output of that resonator.

4. The apparatus of claim 1, wherein:
the interdigital transducers in a first of the resonators are coupled in parallel between an input of the first resonator and ground;
the interdigital transducers in a second of the resonators are coupled in series between the input of the first resonator and an output of the second resonator; and
the interdigital transducers in a third of the resonators are coupled in parallel between the output of the second resonator and ground.

5. The apparatus of claim 4, wherein each of the first, second, and third resonators includes two interdigital transducers and three reflectors.

6. The apparatus of claim 4, wherein:
each of the interdigital transducers includes multiple sets of electrodes;
at least some of the reflectors are electrically coupled to at least some of the sets of electrodes in the interdigital transducers; and
at least some of the reflectors are electrically coupled together.

7. The apparatus of claim 1, wherein:
the interdigital transducers in a first of the resonators are coupled in series between an input of the first resonator and an output of the first resonator;
the interdigital transducers in a second of the resonators are coupled in parallel between the output of the first resonator and ground; and
the interdigital transducers in a third of the resonators are coupled in series between the output of the first resonator and an output of the third resonator.

8. The apparatus of claim 7, wherein each of the first, second, and third resonators includes two interdigital transducers and three reflectors.

9. The apparatus of claim 1, wherein the plurality of resonators forming the filter comprise resonators forming at least two Π sections or at least two T sections in the filter.

10. A system comprising:
a signal source configured to provide a signal; and
a filter configured to filter the signal, the filter comprising a plurality of resonators, at least one of the resonators comprising:
a plurality of interdigital transducers positioned in a common acoustic track; and
a plurality of reflectors configured to reflect acoustic waves from the interdigital transducers back to the interdigital transducers, wherein at least one reflector is positioned between adjacent interdigital transducers.

11. The system of claim 10, wherein:
the interdigital transducers in a first of the resonators are coupled in parallel between an input of the first resonator and ground;
the interdigital transducers in a second of the resonators are coupled in series between the input of the first resonator and an output of the second resonator; and
the interdigital transducers in a third of the resonators are coupled in parallel between the output of the second resonator and ground.

12. The system of claim 11, wherein:
each of the interdigital transducers includes multiple sets of electrodes;
at least some of the reflectors are electrically coupled to at least some of the sets of electrodes in the interdigital transducers; and
at least some of the reflectors are electrically coupled together.

13. The system of claim 10, wherein:
the interdigital transducers in a first of the resonators are coupled in series between an input of the first resonator and an output of the first resonator;
the interdigital transducers in a second of the resonators are coupled in parallel between the output of the first resonator and ground; and
the interdigital transducers in a third of the resonators are coupled in series between the output of the first resonator and an output of the third resonator.

14. The system of claim 10, further comprising:
a signal processor configured to process a filtered signal provided by the filter.

15. The system of claim 10, wherein the signal source comprises an antenna.

16. The system of claim 10, wherein the plurality of resonators forming the filter comprise resonators forming at least two Π sections or at least two T sections in the filter.

17. A resonator comprising:
a plurality of interdigital transducers positioned in a common acoustic track; and
a plurality of reflectors configured to reflect acoustic waves from the interdigital transducers back to the interdigital transducers, wherein at least one reflector is positioned between adjacent interdigital transducers.

18. The resonator of claim 17, wherein the interdigital transducers are coupled in parallel between an input and an output of the resonator.

19. The resonator of claim 17, wherein the interdigital transducers are coupled in series between an input and an output of the resonator.

20. The resonator of claim 17, wherein:
each of the interdigital transducers includes multiple sets of electrodes; and
at least some of the reflectors are electrically coupled to at least some of the sets of electrodes in the interdigital transducers.
